(19) United States
(12) Patent Application Publication
(10) Pub. No.: US 2021/0242589 A1
(43) Pub. Date: Aug. 5, 2021

(54) COIL AND DEVICE FOR WIRELESS SIGNAL TRANSMISSION, AND METHOD FOR PRODUCING SUCH A COIL

(71) Applicant: OTTO-VON-GUERICKE-UNIVERSITÄT MAGDEBURG, Magdeburg (DE)

(72) Inventors: Enrico PANNICKE, Magdeburg (DE); Marcus PRIER, Magdeburg (DE)

(21) Appl. No.: 17/049,159

(22) PCT Filed: Apr. 16, 2019
(86) PCT No.: PCT/EP2019/059827

§ 371 Date: Oct. 20, 2020

(30) Foreign Application Priority Data
Apr. 20, 2018 (DE) 10 2018 109 540.6

(51) Int. Cl. H01Q 7/00

(52) U.S. Cl. CPC H01Q 7/00; H04B 1/40

(57) ABSTRACT

The invention relates to a coil in the form of a transmitting and/or receiving coil of a device for wireless signal transmission by means of electromagnetic waves, wherein the coil has an impedance matching circuit for adapting the connection impedance of the coil to an input impedance of a signal transmitting and/or receiving device of the device for wireless signal transmission to be connected to the coil, wherein the impedance matching circuit is formed entirety or at least partially by at least partially overlapping conductor tracks of the coil. The invention also relates to a device for wireless signal transmission by means of electromagnetic waves, comprising a signal transmitting and/or receiving device and a coil connected to the signal transmitting and/or receiving device. The invention further relates to a method for producing such a coil.)

The invention relates to a coil in the form of a transmission and/or reception coil of a device for wireless signal transmission, for example by way of electromagnetic waves, or for wireless signal reception, wherein the coil has an impedance matching circuit for matching the connection impedance of the coil to an input impedance of a signal transmission and/or reception device, to be connected to the coil, of the device for wireless signal transmission. The invention furthermore relates to a device for wireless signal transmission or for wireless signal reception, having a signal transmission and/or reception device and a coil connected to the signal transmission and/or reception device. The invention furthermore relates to a method for producing such a coil.

Such devices for wireless signal transmission are encountered in various technological fields. The field of magnetic resonance tomography (MRT) may be mentioned as an example. In this case, strong magnetic fields are emitted by way of such a coil, and resulting effects on a person to be examined are received again by such a coil. Other fields of application for such coils may be encountered for example in energy harvesting or in the transmission of RFID signals.

Wireless signal transmission is understood in this case to mean signal transmission in the broadest sense, that is to say any emission of signals, even if they are not evaluated, any reception of signals and any transmission of signals between a transmitter and a receiver. Such transmission and reception coils are used in the field of magnetic resonance tomography, but no direct signal transmission takes place between these transmission and reception coils. The transmission coil uses a quantum mechanical effect that leads to the generation of externally effective magnetization. This occurs when a spin assembly is exposed to a strong static magnetic field and high-frequency alternating field at what is known as the Larmor frequency. The high-frequency alternating field is generated in this case by the transmission coil. At a different time, the reception coil may receive the induced signal through the temporally variable magnetization. For use in magnetic resonance tomography, the coil according to the invention is therefore particularly suitable for signal reception of the induced signal.

It is known that when connecting such components, such as a coil and a signal transmission and/or reception device, impedance matching is necessary in order to achieve optimal results in terms of the signal transmission. In the case of MRT coils, this is achieved for example using a circuit of capacitors that are attached directly to the coil, for example by soldering them to conductor runs or connection lines of the coil. This however leads to stiffening of the structures in the arrangement, which may reduce flexibility and reliability since for example potential breakage points are created. In some applications, for example for magnetic resonance tomography, the coils should however be as flexible as possible in order to be able to integrate them into an operating gown, for example.

A device for nuclear magnetic resonance (NMR) and a corresponding coil are known from U.S. Pat. No. 5,049,821.

The invention is therefore based on the object of achieving the required impedance matching without the abovementioned disadvantages.

In the case of a coil of the type mentioned at the outset, this object is achieved in that the impedance matching circuit is formed entirely or at least in part by at least partially overlapping conductor runs of the coil. The coil may for example be designed as a conductor loop. The invention has the advantage that impedance matching is able to be achieved with little effort, as a result of which the flexibility and reliability of the coil and of the entire arrangement formed thereby are not impaired. Depending on the design of the coil, complete impedance matching is able to be achieved through the at least partially overlapping conductor runs, such that no further components at all are required to implement the impedance matching circuit. In some cases, it may also be advantageous to implement only part of the impedance matching circuit through the at least partially overlapping conductor runs, for example so as thereby to replace a capacitor connected in parallel with the coil in conventional matching networks.

Implementing at least part of the impedance matching circuit through the overlapping conductor runs is possible because the overlapping conductor runs against one another in turn form capacitances that may be used to achieve the impedance matching. If for example the abovementioned parallel-connected capacitor is intended to be replaced in terms of its function by the overlapping conductor runs, the natural resonance of the conductor runs of the coil may be used for this purpose. Every conductor loop in principle has an intrinsic resonance and may therefore be considered to be an oscillating circuit. By correspondingly matching this resonance behavior, the coil may thus be matched such that the function of the parallel-connected capacitor is replaced by the intrinsic resonance.

Matching the resonance behavior by using the intrinsic resonance is subject in some cases to external restrictions, such as for example a desired diameter of the coil, which may not allow complete matching of the resonance behavior at the desired operating frequency. At least partial matching may therefore be performed using the natural resonance of the conductor runs, and complete matching may be achieved by adding for example a series-connected capacitor.

A distributed capacitance is thus introduced through the partial overlapping of the conductor runs, wherein the intrinsic capacitance is able to be changed through lengthening or shortening the conductor runs in order thereby to achieve the desired impedance matching on the coil side. If the conductor tracks of the coil are overlapped, they form a capacitance, and the resonance of the conductor loop system may be varied with fixed diameters.

According to one advantageous development of the invention, there is provision for connection lines of the coil, which are used to connect the coil to the signal transmission and/or reception device, to be connected to the conductor runs of the coil outside of the area of overlap of the overlapping conductor runs of the coil. The desired transmission or reception function of the coil and the impedance matching are thereby able to be achieved using the conductor runs of the coil. The connection lines of the coil may in this regard be designed to be neutral, for example in the form of a cable designed with the connection impedance of the coil, for example a coaxial cable.

The conductor runs of the coil, which may also be referred to as conductor tracks, may for example have a circular cross-sectional shape.

According to one advantageous development of the invention, there is provision for the area of overlap to extend over an angular range that is not a multiple of 360 degrees. By way of example, the area of overlap may deviate from a multiple of 360 degrees by at least +15 degrees/−15 degrees. The angle specifications refer to a circle of 360 degrees (360°).

According to one advantageous development of the invention, there is provision for the conductor runs of the coil to have, at least partially or completely, a flattened cross-sectional shape. The cross-sectional shape may for example be substantially rectangular, wherein the corners of the rectangular shape may also be rounded. The cross-sectional shape may in particular have a ratio of height to width of less than 1:3 or less than 1:5. The area of overlap between the conductor runs of the coil may thereby be optimized with regard to the intrinsic capacitance formed thereby.

According to one advantageous development of the invention, there is provision for the conductor runs of the coil to be formed, at least partially or completely, from flexible circuit board material. This allows simple and inexpensive provision of such a coil with sufficient flexibility. The coil is therefore suitable for example for applications in medical technology, for example for magnetic resonance tomography.

According to one advantageous development of the invention, there is provision for the coil to be designed as an air-cored coil. The coil is accordingly designed without a core. The coil may for example have an inside diameter that is at least 10 times greater than the width of the conductor runs of the coil.

The object mentioned at the outset is furthermore achieved by a device for wireless signal transmission or for wireless signal reception, having a signal transmission and/or reception device and a coil connected to the signal transmission and/or reception device, wherein the device is coupled to the coil by a decoupling circuit and a connecting line. The coil may in this case be designed as a coil of the type explained above, the connection impedance of which is completely or partially matched to the input impedance of the signal transmission and/or reception device by way of the at least partially overlapping conductor runs. The advantages explained above may also be achieved thereby.

According to one advantageous development of the invention, there is provision for the decoupling circuit to be designed as an active decoupling circuit, by way of which the coil is operated outside of its intrinsic resonance during operation as a transmission coil. This has the advantage that it is possible to guarantee, during the transmission process, that the coil does not exhibit any resonant behavior that interferes with the signal transmission. In particular when using the coil for magnetic resonance tomography, undesired variation in the transmission field and thus deterioration in the imaging of the magnetic resonance tomography is thereby able to be avoided.

According to one advantageous embodiment of the invention, there is provision for the active decoupling circuit to have a diode, for example a PIN diode. The diode may in particular be arranged at the output of the decoupling circuit, that is to say it may be connected upstream of the downstream signal transmission and/or reception device. The diode may in this case be connected directly to the downstream signal transmission and/or reception device, or indirectly via at least one further component, for example via a series-connected capacitor.

In its conductive state, the diode short-circuits an upstream filter, as a result of which the circuit is neutralized with respect to the connected connecting line to the coil, which may be designed as a λ/2 connecting line. In the blocking state, the diode acts like a capacitor, as a result of which the filter circuit performs the function of a phase shifter. The filter circuit may be designed for example as a λ/4 filter, for example as a Collins filter.

If the diode is connected to the signal transmission and/or reception device via the series-connected capacitor, then, as an additional development of the invention, it is possible to independently tune the two states that may be caused by the diode (diode in the conductive state/diode in the blocking state).

According to one advantageous embodiment of the invention, there is provision for the device to be coupled to the coil via the active decoupling circuit and a connecting line (for example connecting cable), wherein the arrangement consisting of the active decoupling circuit and the connecting line has an electrical length of (2.n-1)·λ/4, wherein n is a natural number and lambda (λ) is the wavelength. n may in this case in principle be any natural number greater than 0, for example n=1, 2, 3 and so on. It has thus been recognized that a particularly advantageous connection of the coil to the device is possible via a connecting network that has a total electrical length of an odd multiple of λ/4. This is particularly advantageous when the coil is used only as a reception coil.

The object mentioned at the outset is furthermore achieved by a method for producing a coil of the type explained above, wherein the area of overlap in which the at least partially overlapping conductor runs of the coil are formed is changed through lengthening or shortening until the connection impedance of the coil reaches a predefined impedance value. The advantages explained above may also be achieved thereby.

By way of example, the connection impedance of the coil may be 50 ohms or 25 ohms.

The invention will be explained in more detail below on the basis of exemplary embodiments using drawings.

In the figures:

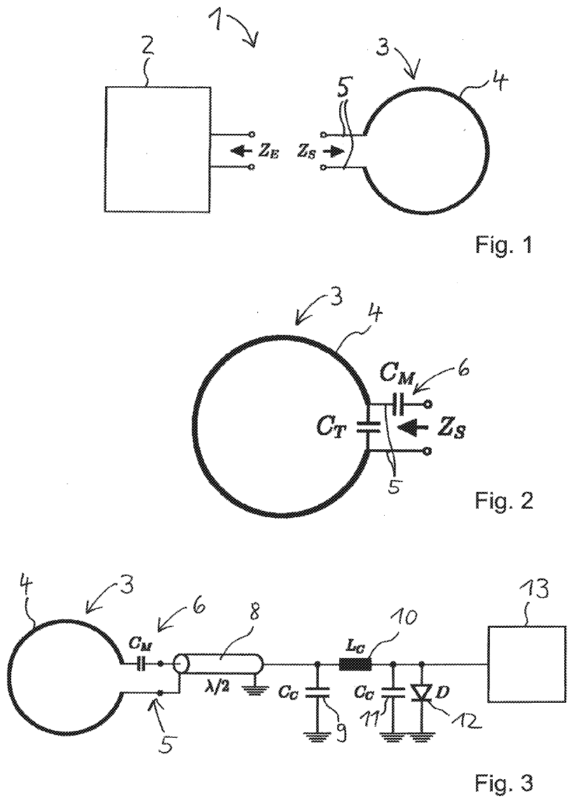

FIG. 1 shows a device for wireless signal transmission and

FIG. 2 shows a coil and

FIG. 3 shows a coil with an active decoupling circuit and

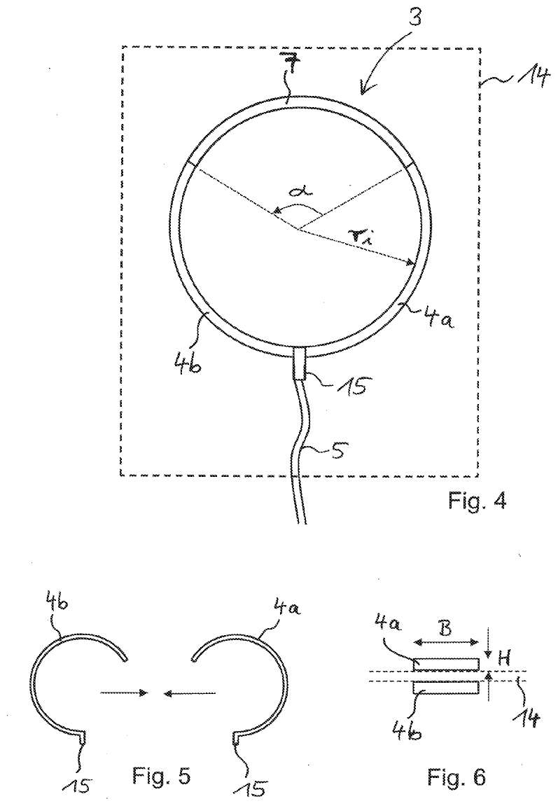

FIG. 4 shows a further embodiment of a coil and

FIG. 5 shows the individual conductor runs of the coil according to FIG. 4 and

FIG. 6 shows a cross section through the conductor runs of the coil according to FIG. 4 and

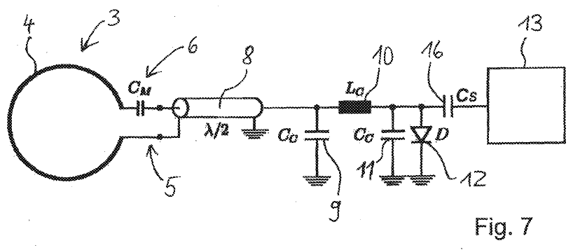

FIG. 7 shows a coil with an active decoupling circuit in a further embodiment.

FIG. 1 illustrates a device 1 for wireless signal transmission by way of electromagnetic waves. The device 1 has a signal transmission and/or reception device 2, which has an input impedance ZE. A coil 3 having conductor runs 4 is also illustrated as part of the device 1. The conductor runs 4 of the coil 3 are connected to connection lines 5 of the coil 3. The coil 3 is able to be connected, via the connection lines 5, to the connections, having the input impedance ZE, of the signal transmission and/or reception device 2. In the illustrated example, the coil 3 has a connection impedance ZS. The aim is then to match the connection impedance ZS to the input impedance ZE.

To this end, the coil 3 may be provided with an impedance matching circuit 6, for example a matching network formed from capacitors, as shown in FIG. 2. The impedance matching circuit 6 may for example have a tuning capacitor CT connected in parallel with the coil 3 and a matching capacitor CM connected in series with the coil 3. The tuning capacitor CT, with the inductance of the conductor runs 4, forms a resonant circuit. The real part of the impedance ZS may be set to the desired impedance value of for example 50 ohms using the tuning capacitor CT. The remaining imaginary part may be compensated with the matching capacitor CM, such that the complex input impedance ZS then has the desired value of for example 50 ohms.

FIG. 3 shows the use of a coil 3 of the type described above in connection with an active decoupling circuit 9, 10, 11, 12. The coil 3 is connected to this decoupling circuit via its connection lines 5 and an impedance-matched connecting line 8. In the present example, it is assumed that the matching capacitor CM is still present on the coil side.

The decoupling circuit has a first capacitor 9 that is connected to the connecting line 8 and is grounded. An inductor 10 is connected thereto in series. A further capacitor 11, in parallel with a diode 12, is arranged downstream of the inductor 10, wherein the further capacitor 11 and the diode 12 are grounded. The capacitors 9, 11 form a filter circuit with the inductor 10. The common connection of the components 10, 11, 12 is connected to a preamplifier 13, which may be connected to the signal transmission and/or reception device 2. By virtue of this decoupling circuit 9, 10, 11, 12, the resonant behavior of the coil 3, that is to say the intrinsic resonant circuit of the coil, is able to be decoupled when using said coil in a transmission process by suppressing the current in the coil through an impedance transformation.

FIG. 7 illustrates a further embodiment of such a decoupling circuit, via which the coil 3 is connected to a preamplifier 13. In contrast to the embodiment in FIG. 3, a further capacitor 16 is connected in series at the output of the decoupling circuit, that is to say downstream of the parallel circuit consisting of the diode 12 and the capacitor 11. The diode 12 is thus connected to the preamplifier 13 via the capacitor 16. This additional capacitor 16 allows independent tuning of the states that arise in the two switching states of the diode 12.

The described impedance matching circuit 6 may be formed completely or at least partially by at least partially overlapping conductor runs 4 of the coil 3, this being illustrated by way of example in FIG. 4. It is assumed that a lower layer 4b of the conductor runs in an area of overlap 7 overlaps an upper layer 4a of the conductor runs in an angular range a. As may be seen, the area of overlap 7 extends over an angular range a that is not a multiple of 360 degrees. By way of example, the angular range a may be in the range from 90 degrees to 270 degrees.

The conductor runs 4a, 4b are connected to conductors of the connection line 5 via respective connection points 15. The conductor runs 4a, 4b may be designed for example as conductor tracks on a circuit board 14, for example a flexible circuit board.

This may accordingly be a circuit board 14 coated on both sides with conductive material, one conductor run 4a being formed on one side of the circuit board and the other conductor run 4b being formed on the opposite side of the circuit board 14.

FIG. 5 illustrates the appearance of the individual conductor runs 4a, 4b when they are not illustrated in overlapping form. The conductor runs 4a, 4b may for example have something like a sickle shape.

FIG. 6 shows a cross section through the arrangement according to FIG. 4 in the area of overlap 7. It may be seen that the conductor runs 4a, 4b have a comparatively large width B in relation to their height H, for example a width B at least five times greater than height H. It may also be seen from FIG. 4 that the inside diameter of the coil 3, characterized by 2ri, is significantly greater than the width B of the conductor runs 4a, 4b, for example at least ten times greater than the width B.

1. A transmission and/or reception coil of a device for wireless signal transmission or for wireless signal reception, comprising:
an impedance matching circuit for matching connection impedance of the coil to an input impedance of a signal transmission and/or reception device
wherein the impedance matching circuit is formed entirely or at least in part by at least partially overlapping conductor runs of the coil.

2. The coil as claimed in claim 1, further comprising:
connection lines which are used to connect the coil to the signal transmission and/or reception device,
wherein the connection lines are connected to the conductor runs of the coil outside of an area of overlap of the conductor runs of the coil.

3. The coil as claimed in claim 2 wherein the area of overlap extends over an angular range that is not a multiple of 360 degrees.

4. The coil as claimed in claim 1 wherein the conductor runs have, at least partially or completely, a flattened cross-sectional shape.

5. The coil as claimed in claim 1 wherein the conductor runs are formed, at least partially or completely, from flexible circuit board material.

6. The coil as claimed in claim 1 wherein the coil is configured as an air-cored coil.

7. A device for wireless signal transmission or for wireless signal reception, comprising:
a signal transmission and/or reception device; and
a coil connected to the signal transmission and/or reception device; and
a decoupling circuit and a connecting line configured to couple the device to the coil.

8. The device as claimed in claim 7, wherein the coil comprises
an impedance matching circuit for completely or partially matching connection impedance of the coil to an input impedance of the signal transmission and/or reception device,
wherein the impedance matching circuit is formed entirely or at least in part by at least partially overlapping conductor runs of the coil.

9. The device as claimed in claim 7 wherein the decoupling circuit has a filter circuit.

10. The device as claimed in claim 7 wherein the decoupling circuit is designed as an active decoupling circuit, by way of which the coil is operated outside of an intrinsic resonance during operation as a transmission coil.

11. The device as claimed in claim 10 wherein the active decoupling circuit has a diode.

12. The device as claimed in claim 7 wherein the decoupling circuit and the connecting line has an electrical length of (2·n-1)·λ/4, wherein n is a natural number and lambda (λ) is the wavelength.

13. A method for producing a coil as claimed in claim 1 wherein the area of overlap is changed through lengthening or shortening until the connection impedance of the coil reaches a predefined impedance value.
